(19) United States
(12) Patent Application Publication
(10) Pub. No.: US 2026/0269475 A1
(43) Pub. Date: Sep. 10, 2026

(54) PHASED ARRAY ANTENNAS EMPLOYING ANTENNA ELEMENT SYSTEM IN PACKAGE

(71) Applicants: Noel LOPEZ, Carlsbad, CA (US); Adam WEIDLING, Carlsbad, CA (US); VIASAT, INC., CARLSBAD, CA (US)

(72) Inventors: Noel Lopez, Chandler, AZ (US); Adam Weidling, Gilbert, AZ (US)

(21) Appl. No.: 19/168,422

(22) PCT Filed: Mar. 27, 2024
(86) PCT No.: PCT/US2024/021698

§ 371 Date: Sep. 24, 2025

Related U.S. Application Data
(60) Provisional application No. 63/492,443, filed on Mar. 27, 2023.

(51) Int. Cl. H01Q 9/04; H01Q 3/28; H01Q 3/38

(52) U.S. Cl. CPC H01Q 9/0414; H01Q 3/28; H01Q 3/38

(57) ABSTRACT

Disclosed is a phased array antenna including a first component layer with a plurality of antenna elements supported by at least one antenna substrate. A second component layer underlies the first component layer and includes a plurality of RF integrated circuit (RFIC) chips each comprising at least one amplifier, and each being RF coupled to at least one of the antenna elements through the at least one antenna substrate. A third component layer underlies the second component layer and comprises a plurality of phase shifters electrically coupled to the plurality of amplifiers, for steering a beam formed by the plurality of antenna elements.

### TECHNICAL FIELD

This disclosure relates generally to antennas and more particularly to component packaging structures for active phased array antennas.

### DISCUSSION OF RELATED ART

Antenna arrays are currently deployed in a variety of applications at microwave and millimeter wave frequencies, such as in aircraft, satellites, vehicles, radar, and base stations for general communications. Such antenna arrays typically include microstrip radiating elements driven with phase shifting beamforming circuitry to generate a phased array for beam steering. In many cases it is desirable for an entire antenna system, including the antenna array and beamforming circuitry, to occupy minimal space with a low profile while still meeting requisite performance metrics. To this end, a thin, generally planar structure for an antenna apparatus is desirable. The structure may have a sandwich type configuration including antenna elements disposed in an exterior facing component layer and integrated circuits (ICs) distributed across a parallel component layer behind the antenna element layer. The ICs may include RFICs with front end circuitry such as RF power amplifiers (PAS) for transmit operations, low noise amplifiers (LNAs) for receive operations, and phase shifters for beam steering.

At high operating frequencies such as mm wave frequencies (e.g., 30 GHz and above), a desirable inter-element spacing between radiating elements, e.g., a maximum of half a wavelength (½), is very small, e.g., 5 mm at 30 GHz and linearly smaller at still higher frequencies. At these frequencies it is difficult to package the requisite electronics of a phased array antenna system in a constrained space and also meet requisite performance objectives.

### SUMMARY

In an aspect of the presently disclosed technology, a phased array antenna includes a first component layer with a plurality of antenna elements supported by at least one antenna substrate. A second component layer underlies the first component layer and includes a plurality of RF integrated circuit (RFIC) chips each comprising at least one amplifier, and each being RF coupled to at least one of the antenna elements through the at least one antenna substrate. A third component layer underlies the second component layer and comprises a plurality of phase shifters electrically coupled to the plurality of amplifiers, for steering a beam formed by the plurality of antenna elements.

The phased array antenna may be formed as at least one antenna element system in package (AESiP). Multiple AESiPs may be integrated together as subarrays of a larger phased array.

In another aspect, a phased array antenna includes a plurality of AESiPs, each forming a subarray of the phased array antenna and each being configured with the first to third component layers as summarized above. The phased array antenna further includes a combiner/divider configured to combine a plurality of receive path signals derived from signals received and phase shifted by the phase shifters of the AESiPs to provide a composite receive path signal, and/or to divide an input transmit path signal into a plurality of divided transmit path signals which are output to the phase shifters.

### BRIEF DESCRIPTION OF THE DRAWINGS

The above and other aspects and features of the disclosed technology will become more apparent from the following detailed description, taken in conjunction with the accompanying drawings in which like reference numerals indicate like elements or features. Various elements of the same or similar type may be distinguished by annexing the reference label with an underscore/dash and second label that distinguishes among the same/similar elements (e.g., _1, _2), or directly annexing the reference label with a second label. However, if a given description uses only the first reference label, it is applicable to any one of the same / similar elements having the same first reference label irrespective of the second label. Elements and features may not be drawn to scale in the drawings.

FIG. 1 is an end view of an example phased array antenna according to an embodiment.

FIG. 2 is an example top view of the phased array antenna of FIG. 1.

FIG. 3 schematically illustrates example circuit elements of the phased array antenna of FIG. 1.

FIG. 4A illustrates example connection arrangements and structures in the phased array antenna of FIG. 1.

FIG. 4B illustrates an example arrangement of through substrate vias (TSVs) in a cross-sectional view of an RFIC chip.

FIG. 4C shows an example arrangement of TSVs in a cross-sectional view of an interposer component.

FIG. 5 is an end view of an example phased array antenna in which RFICs are each RF coupled to multiple antenna elements.

FIG. 6 is an end view of an example phased array antenna in which an interposer layer is configured with multiple chips.

FIG. 7 is an end view of an example phased array antenna in which a single antenna substrate supports all the antenna elements of the array;

FIG. 8 schematically illustrates an example arrangement of beamforming components within any RFIC chip and interposer in the antennas of FIGS. 1, 5, 6 or 7, when antenna element sharing between transmit and receive operations is implemented.

FIG. 9A is an end view of an example phased array antenna configured with a plurality of subarray antennas of any of FIGS. 1, 5, 6 or 7.

FIG. 9B is a plan view of the phased array antenna of FIG. 9A.

### DETAILED DESCRIPTION OF EMBODIMENTS

The following description, with reference to the accompanying drawings, is provided to assist in a comprehensive understanding of certain exemplary embodiments of the technology disclosed herein for illustrative purposes. The description includes various specific details to assist a person of ordinary skill in the art with understanding the technology, but these details are to be regarded as merely illustrative. For the purposes of simplicity and clarity, descriptions of well-known functions and constructions may be omitted when their inclusion may obscure appreciation of the technology by a person of ordinary skill in the art.

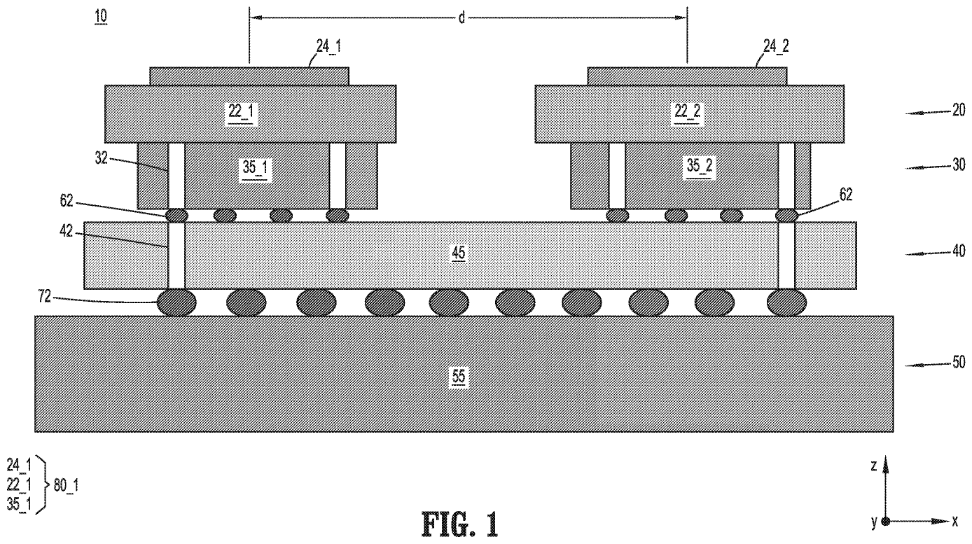

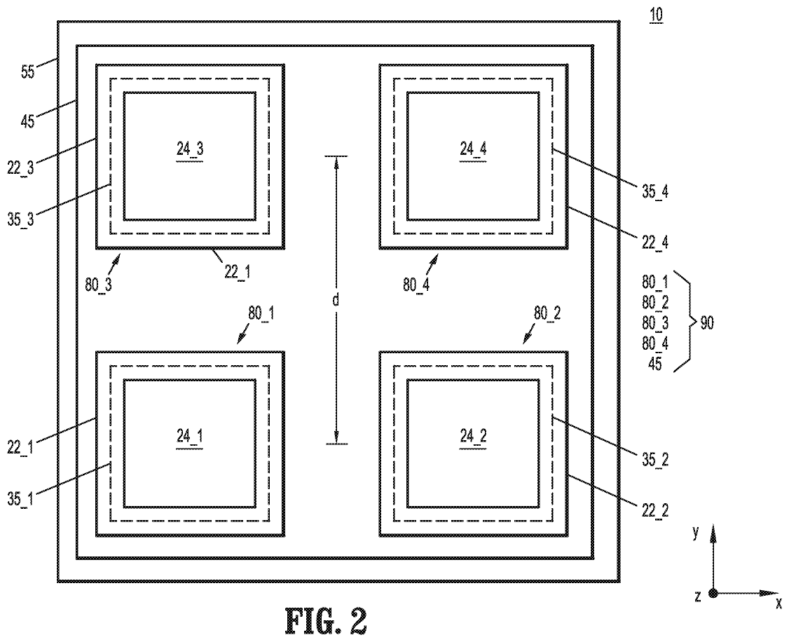

FIG. 1 is an end view of an example phased array antenna, 10, according to an embodiment. FIG. 2 is an example top view of phased array antenna 10. Referring to FIGS. 1 and 2, phased array antenna 10 (hereafter, “antenna 10”) may be either a stand-alone phased array antenna or a subarray of a larger phased array antenna. Antenna 10 can also be an example of an “antenna element system in package” (AESiP), discussed below. Antenna 10 is configured in a stacked structure and may have first through fourth component layers 20, 30, 40 and 50 stacked upon one another in a thickness direction of the antenna 10 (hereafter referred to as the vertical or “z” direction for convenience of explanation).

First component layer 20 includes a plurality N of radiating elements (“antenna elements”) 24 supported by at least one dielectric antenna substrate 22, to form a planar, linear, or three dimensional array. The example of FIGS. 1-2 shows a 2×2 square array of antenna elements 24_1 to 24_4. In other examples, antenna 10 is a 1×2 array, a 3×3 array, or a 4×4 array, etc. In general, N may be any suitable number of antenna elements 24, arranged either uniformly in the same or different numbers of columns and rows, or in a staggered configuration.

The arrangement of antenna elements 24 may be sufficient to form a radiating aperture with any desired shape, such as square, rectangular or circular. A virtual lattice connecting central points of the antenna elements 24 may form a rectangular, square, triangular or other geometrically shaped lattice. In FIGS. 1-2, the at least one antenna substrate includes segregated antenna substrate sections 22_1 to 22_4, each supporting one antenna element 24_1 to 24_4, respectively. In other examples, any antenna substrate section 22 supports two or more antenna elements 24. Antenna elements 24 may be any suitable type, e.g., printed microstrip patches, dipoles, or slot elements.

Second component layer 30 may be adhered to and directly underly the first component layer 20. In general, second component layer 30 may include antenna front-end components which include a plurality of active beamforming elements, e.g., amplitude adjusters (amplifiers and/or controllable variable attenuators), phase shifters, true time delays, and/or switches, and may further include passive front-end components such as filters and impedance matching structures. Because second component layer 30 includes such active beamforming elements distributed across the antenna array aperture, directly behind the antenna substrate(s) supporting the antenna elements, phased array antenna 10 may be characterized as an “active phased array”.

The following discussion will describe an example of the second component layer 30 including amplifiers for transmit and/or receive operations. Second component layer 30 may be formed by a plurality of radio frequency (RF) integrated circuit (RFIC) chips 35, e.g. microwave ICs (MICs) or monolithic microwave ICs (MMICs). (Herein, “radio frequency” encompasses microwave and millimeter (mm) wave frequencies and can be any frequency at which a wireless signal can propagate in free space.) For instance, FIGS. 1-2 depict the second component layer 30 including RFIC chips 35_1 to 35_4, each underlying and adhered to one of antenna substrate sections 22_1 to 22_4, respectively.

A redistribution layer (RDL) 26 may be included at a lower end of an antenna substrate 22, thus forming a part of the antenna substrate 22.

Alternatively, RDL layer 26 is formed atop an RFIC chip 35 and may be considered part of the RFIC chip 35. RDL layer 26 may include at least one metal layer for routing RF signals, control signals and/or bias voltages, and/or providing a ground surface, and at least one dielectric layer to isolate the at least one metal layer from other conductors. At least one additional RDL (not shown) may be included to facilitate routing of signals between adjacent component layers, e.g., an RDL between the third and fourth component layers 40 and 50, and/or another RDL between the second and third component layers 30 and 40.

Any RFIC chip 35 may be RF coupled (electrically connected or electromagnetically (EM) coupled to communicate an RF signal) to a single antenna element 24 or to multiple antenna elements 24. Electrical connection between an RFIC chip 35 to an antenna element 24 may be made through at least one through substrate via (TSV) (not shown) within the substrate section 22 supporting the antenna element(s) 24. The TSV may form a probe feed (connecting directly to the antenna element 24's aperture) or may connect to a conductive trace extending from a side portion of the antenna element 24. EM coupling to excite an antenna element 24 may be done in any suitable way, such as with a blind via extending from the lower end of the antenna substrate section 22, through radiation from a solder ball (not shown) between the RFIC chip 35 and the antenna substrate section 22, or through a coupling structure in the RDL 26. An RFIC chip 35 may further include one or more TSVs 32 that may be used to transfer heat away from the RFIC chip 35 to the third component layer 40. One or more TSVs 32 within an RFIC chip 35 may also be grounded, which may serve to provide RF isolation and/or suppress cavity modes at or near the frequencies of operation of circuit elements. Such cavity modes may otherwise cause oscillations and/or unwanted coupling between circuit elements or signal paths.

Third component layer 40 also includes a plurality of active beamforming (BF) elements, e.g., phase shifters, amplitude adjusters, true time delays, and/or switches, and may further include passive circuit elements. BF elements are circuit elements that contribute to forming/steering the beam. Third component layer 40 may be adhered to second component layer 30 with a plurality of interconnects 62, sometimes called conductive joints, which may be solder balls or metal pillars (e.g., copper pillars). Third component layer 40 may be configured as a plate-shaped beamforming network (BFN) component, herein called an “interposer” 45, which includes at least one substrate supporting beamforming elements.

Interposer 45 is interposed between RFIC chips 35 and the fourth component layer 50. Interposer 45 may be one or more chips (dies) cut from a wafer, or it may be a wafer itself. The substrate material of the chips/wafer supports the beamforming elements, in that the beamforming elements may be formed on a surface of the substrate or embedded within the substrate. In antenna 10 of FIGS. 1-2, interposer 45 has a profile in the horizontal plane (the xy plane illustrated) extending across at least a plurality of the RFIC chips 35. Thus, interposer 45 underlies at least two RFIC chips 35. In other embodiments such as those discussed later, interposer 45 comprises a plurality of chips, the horizontal profile of each of which is approximately equal to that of an RFIC chip 35, such that each of these chips underlies only a single RFIC chip 35.

Fourth component layer 50 may be a printed wiring board (PWB) 55, and may include a combiner/divider network, biasing circuitry and control circuitry (discussed below). PCB 55 may be adhered to interposer 45 through interconnects 72, at least some of which make electrical connections to route signals to and from PCB 55 and interposer 45.

The following discussion will describe an example of interposer 45 including a plurality of phase shifters for steering an antenna beam formed by the antenna elements 24. Herein, “steering” an antenna beam encompasses setting up a beam to point in a desired direction by appropriate settings of the phase shifts provided by the phase shifters. Once the beam is set up, it may remain fixed or it may be steered to another direction by changing the phase shifts of the individual phase shifters using control signals applied from the fourth component layer 50.

In some related art active phased array antennas, RFIC chips that are directly attached to the antenna substrate include both amplifiers and phase shifters. On the other hand, in some embodiments herein, the RFIC chips 35 exclude phase shifters. By configuring the RFIC chips 35 without phase shifters, they may have a smaller profile in the horizontal (xy) plane. Since RFIC chips 35 are coupled to antenna elements 24 through an RF interface at the lower surface of antenna substrate 22, the provision of the RFIC chips 35 with a smaller profile allows for the inter-element spacing “d” between antenna elements 24 to be smaller. Since a desired inter-element spacing (e.g., a maximum of λ/2) decreases linearly with frequency, the configuration of antenna 10 with smaller RFIC chips 35 enables operation at higher frequencies than those possible in the comparable related art array antennas. Alternatively or additionally, by providing RFIC chips 35 without phase shifters, additional circuitry for added functionality may be included in RFIC chips 35.

Moreover, in some related art antennas, the RFIC chips attached on their upper sides to the antenna substrates may be attached on their lower sides to a PWB. Since PWB materials have low thermal conductivity, e.g., in the range of 0.3-4 Wn⁻¹K⁻¹, the thermal exchange between the RFIC chips and the PWB may be unsatisfactory, causing the RFIC chips to run too hot and constrain operations. On the other hand, interposer 45 may be composed primarily of a material having a higher thermal conductivity than a PWB, thereby reducing a thermal rise RFIC chips 35 and acting as a heat spreader for RFIC chips 35. Heat may be transferred from RFIC chips 35 to interposer 45 through interconnects 62. A heat sink or cold plate (neither shown) may be attached below PWB 55. Thus, a heat path from RFIC chips 35 to the heat sink/cold plate may include interposer 45 and PWB 55. TSVs 32 and 42, each connected to interconnects 62, may enhance the heat transfer to interposer 45. For instance, in some embodiments, interposer 45 is composed primarily of silicon (Si) which has a thermal conductivity of 148 Wn⁻¹K⁻¹.

In addition, interposer 45 may be primarily composed of a material having a higher thermal conductivity than that of RFIC chips 35. For instance, RFIC chips may be primarily composed of a III-V material such as gallium arsenide (GaAs), gallium nitride (GaN) or indium phosphide (InP) whereas interposer 45 may be primarily composed of silicon (Si), which has a higher thermal conductivity than the former III-V materials. Thus, interposer 45 may operate as an efficient heat sink for RFIC chips 35. For instance, GaAs and GaN have thermal conductivities of 55 and 130 Wn⁻¹K⁻¹, respectively.

Further, by dedicating interposer 45 configured with different types of beamforming elements than those of RFIC chips 35 (e.g., phase shifters in the former, amplifiers in the latter), the flexibility in the manufacturing processes for both RFICs 35 and interposer 45 may be enhanced. Comparatively, in some related art antennas, the manufacturing process for forming RFICs that include both amplifiers and phase shifters may be constrained.

The example plan view of FIG. 2 illustrates that the footprint of an antenna element 24 in the xy (horizontal) plane may be similar to that of an RFIC chip 35. For instance, the surface area of an antenna element 24 in the xy plane may be within +/−10% of that of an RFIC chip 35 underlying it. Meanwhile, antenna 10 may be configured for operation at microwave or millimeter wave frequencies, where microwave frequencies are typically defined as frequencies from 500 MHz to 10 GHz and mm frequencies are typically defined as frequencies from 10 GHz to 100 GHz and higher. The higher the frequency, the more difficult it is to package antenna array front-end electronics close to the antenna elements in a desirable manner. For example, at 30 GHz, an inter-element spacing “d” of λ/2 is 5 mm, and at 60 GHz, λ/2 is 2.5 mm (inter-element spacings higher than λ/2 may result in grating lobes when the beam is steered to point off boresight). Accordingly, with the stacked component layer structure of antenna 10 and other embodiments herein, RFIC chips 35 may be made small enough to achieve the desired inter-element spacing without degrading other performance metrics.

A set of stacked components of component layers 20, 30 and 40 may be formed and referred to interchangeably as an “active antenna package”, an “active antenna module” or an antenna element system in package (AESiP). For instance, antenna element 24_1, antenna substrate 22_1 and RFIC chip 35_1 are stacked upon each other and together constitute an AESIP 80_1. Likewise, active antenna packages 80_2, 80_3 and 80_4 may be analogously formed. Any package 80 may be performance tested prior to being attached to interposer 45, thereby improving manufacturing yield of antenna 10. As another example, an active antenna package 90 may be constituted by the elements of packages 80_1 to 80_4 adhered to interposer 40. In this case, packages 80_1 to 80_4 may first be formed (and optionally pre-tested) as sub-packages of package 90. Package 90 may be pre-tested prior to integration with PWB 50 to likewise improve manufacturing yield of antenna 10. When antenna 10 is to become a subarray of a larger phased array, PWB 55 may extend across and electrically connect to several or all of the subarrays. In other examples, PWB 55 is part of an AESIP formed in conjunction with the components of antenna element package 90, and may be integrated with other PWBs of other subarrays at a later assembly stage of the larger antenna array.

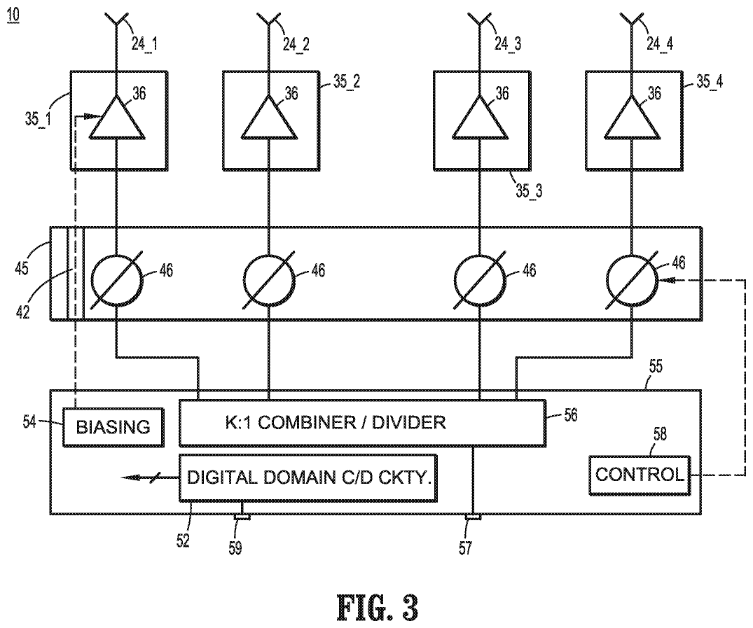

FIG. 3 schematically illustrates example circuit elements and their locations and interconnections in phased array antenna 10. In this example, each RFIC chip 35 includes at least one amplifier 36 that is EM or electrically coupled to a respective antenna element 24. Amplifiers 36 are each illustrated as a transmit amplifier, sometimes called a power amplifier (PA). When an antenna element 24 is dedicated only for transmitting signals to free space, a receive path amplifier (sometimes called low noise amplifiers (LNAs)) may be excluded from the RFIC chip 35 coupled to that antenna element 24. Likewise, when an antenna element 24 is dedicated for receive path operations only, the amplifier 36 within the RFIC chip 35 coupled thereto is an LNA, and a PA may be excluded. To share an antenna element 24 for transmit and receive operations, an RFIC chip 35 may include both a PA and an LNA, along with a transmit/receive (T/R) switch or filtering mechanism to isolate the transmit and receive path signals, as is known in the art. In any case, RFIC chips 35 may further include front-end passive circuitry such as impedance matching circuits, filters (bandpass, low pass, etc.) and a combiner/divider (all not shown) as is known in the art. In some embodiments, an RFIC chip 35 includes multiple RF output ports, each RF coupled to one of antenna elements 24. In this case, a combiner/divider may be included in an RFIC chip 35 to divide an input transmit path RF signal to multiple paths, each connected to a respective input of one of multiple amplifiers 36 in that RFIC chip 35 and/or to combine antenna element signals received from multiple antenna elements 24 and amplified by LNAs 36. In some examples, any of the RFIC chips 35 is RF coupled in this manner to two, three or four antenna elements 24.

Interposer 45 may include phase shifters 46, each coupled to an input of a respective transmit path amplifier 36 on transmit (as illustrated) and/or each coupled to an output of a respective receive path amplifier, if included within the connected RFIC 35. Although not illustrated, interposer 46 may further include amplitude adjusters in the form of variable attenuators and/or amplifiers, as well as passive front-end components.

PWB 55 may include biasing circuitry 54, control circuitry 58 and a K:1 combiner/divider 56. Biasing circuitry 54 may be electrically connected to each of amplifiers 36 to bias the same, where the connections may be made through respective TSVs 42 within interposer 45. In embodiments where interposer 45 includes amplifiers for beam adjustment/scanning, bias circuitry 54 may provide bias voltages to these amplifiers as well. Control circuitry 58 may apply individual control signals to each of phase shifters 46 to individually control their phase shifts in accordance with a desired beam pointing direction. In embodiments where interposer 46 further includes variable attenuators to adjust the beam shape and/or pointing direction, control circuitry 58 may be coupled to such attenuators to effectuate such beam adjustment. In embodiments where RFIC chips 35 include T/R switches for aperture sharing as noted above, control circuitry may be further coupled to these switches to implement the desired switching functionality.

K:1 combiner/divider 56 may be coupled to phase shifters 46 and configured to: (i) combine K receive path signals phase shifted by phase shifters 46 to provide a composite receive path signal at an input/output (I/O) port 57; (ii) divide an input transmit path signal at I/O port 57 into K divided transmit path signals which are respectively output to phase shifters 46; or (iii) perform both the combining and dividing of (i) and (ii). In embodiments where each RFIC chip 35 is RF coupled to only one of the N antenna elements 24, K=N. In embodiments where each or some of the RFIC chips 35 is/are RF coupled to two or more antenna elements 24, some of the combining/dividing can be performed within RFIC chips 35 as noted above, so that K<N. Antenna 10 may also be configured, with suitable design for combiner/divider 56 in conjunction with control of phase shifters 46 (e.g., additional to those for the operations described above) to form multiple simultaneous beams at the same or different frequencies, as is known in the art.

K:1 combiner/divider 56 has been discussed above in the context of an analog domain embodiment. In a digital domain embodiment, PWB 55 may include digital domain combining/dividing (DD_C/D) circuitry 52. For the receive path, DD_C/D circuitry 52 may include a high speed RF signal sampler to sample the output signal from each phase shifter 46 to obtain a real time amplitude and phase value; and a digital summer to “complex value sum” the samples to obtain a composite receive signal in the digital domain at a digital I/O port 59. Alternatively, DD_C/D circuitry 52 includes a downcoverter to downconvert the output signals of phase shifters 46 to baseband; a baseband sampler to sample the baseband signals and a digital summer to complex value sum the baseband samples. Reciprocal operations may be performed in the transmit path by DD_C/D circuitry 52 (using an upconverter and/or a signal synthesizer) to convert a baseband signal into multiple RF signals with a targeted amplitude and phase distribution, which are applied to phase shifters 46 (e.g., in-phase signals with a targeted amplitude distribution across the array aperture). In still another embodiment, a hybrid analog-digital approach employs both combiner/divider 56 (modified as a K:j combiner/divider, where j≥2) which interfaces j outputs/inputs to DD_C/D circuitry 52. DD_C/D circuitry 52 may convert the j analog outputs to a composite digital receive signal, and/or generate and output j RF signals to combiner/divider 56 where they are further divided into K divided transmit signals and applied to phase shifters 46.

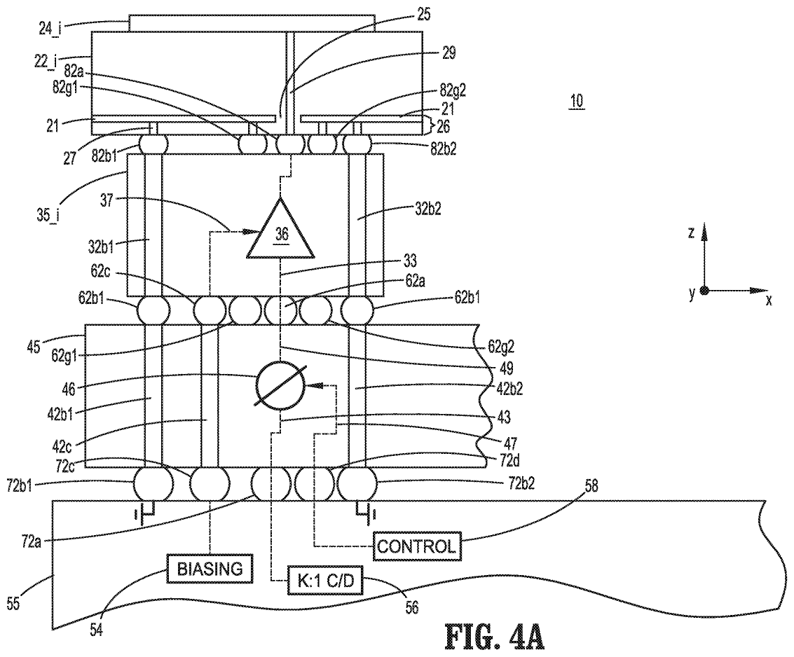

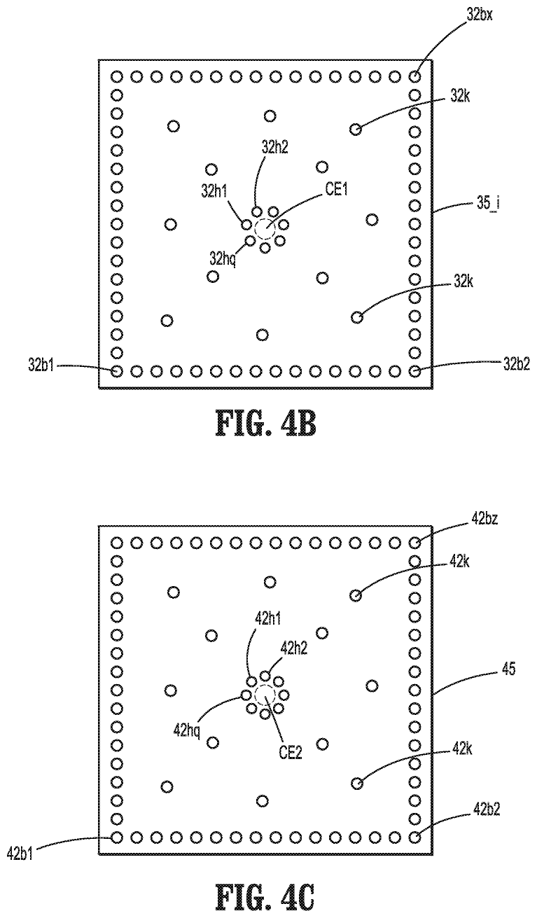

FIG. 4A illustrates example connection arrangements and structures in phased array antenna 10. An RFIC chip 35_i (i=any of 1 through N) is exemplified as including at least one amplifier 36. As mentioned earlier, interposer 45 may include at least one TSV to route biasing and/or control voltages therethrough, from PWB 55 to beamforming elements within RFIC chips 35. For instance, an interconnect 72c may carry a biasing voltage from biasing circuitry 54, which is routed to amplifier 36 through a circuit path including a TSV 42c, an interconnect 62c and a conductive path 37. A phase shift control signal generated by control circuitry 58 may be routed to a phase shifter 46 within interposer 45 through a signal path including an interconnect 72d and a conductive path 47.

An RF signal may be exchanged between phase shifter 46 and K:1 combiner/divider 56 through an RF signal path including interconnect 72a and a signal path 43. An output RF signal from phase shifter may be routed to an input of amplifier 36 through RF signal conductors including conductive path 49, an interconnect 62a and a signal conductor 33. RF shielding for this signal may be provided with grounded conductors on opposite sides or surrounding the signal conductors. For instance, interconnects 62g1 and 62g2 (or 82g1 and 82g2) on opposite sides of interconnect 62a (or interconnect 82a connected to an output of amplifier 36) may be either ground conductors of a ground-signal-ground (GSG) connection, or may be two ground conductors out of three or more ground structures (e.g., all solder balls) surrounding interconnect 62a (or 82a). Although not illustrated, similar ground conductors may be provided on opposite sides of RF interconnect 72a for RF shielding. RF signal conductors such as 33, 43 and 49 may be formed in coplanar waveguide (CPW) or microstrip transmission line mediums.

TSVs 32b1, 32b2 may be “circuit grounded”, e.g., by connection to a “system ground” within PWB 55 through TSVs 42b1, 42b2 and interconnects 72b1, 72b2, respectively. Suitably arranged grounded TSVs (e.g., distributed throughout RFIC 35_i or as fencing around or between circuit elements or signal paths) such as 32b1 and 32b2 (in conjunction with other grounded TSVs) may serve to provide RF isolation and/or suppress cavity modes within RFIC chip 35_i that otherwise cause oscillations and/or unwanted coupling between elements. Similarly, suitably arranged grounded TSVs such as 42b1 and 42b2 (in conjunction with other grounded TSVs) may provide RF isolation and/or suppress cavity modes within interposer 45. For instance, as shown in the example cross-sectional view of FIG. 4B, grounded TSVs 32b1 to 32bx, 32h1 to 32hq, and other distributed grounded TSVs 32k may be provided, where the total number of grounded TSVs within the chip 35_i may be tens, hundreds or upwards of one thousand in a single chip. (At least ten such grounded TSVs in a chip may be included to achieve a practical improvement in performance due to cavity mode suppression.) TSVs 32b1 to 32bx are examples of peripherally located TSVs for inter-chip isolation. TSVs 32h1 to 32hq are examples of locally provided TSVs (for both inter-chip and intra-chip isolation) that annularly surround a circuit element CE1 (e.g., a circuit, circuit component or a signal path) to electromagnetically isolate it from other circuit elements. TSVs 32k are examples of other distributed grounded TSVs that, either as a group or in conjunction with other TSVs like 32b1 to 32bx and/or 32h1 to 32hq, may suppress cavity modes within RFIC chip 35_i. Likewise, as seen in FIG. 4C, grounded TSVs 42b1 to 42bz (peripherally distributed), 42h1 to 42hq (surrounding a circuit element CE2 of interposer 45) and 42k (other distributed) TSVs may afford similar cavity mode suppression and isolation benefits to the circuitry of interposer 45.

It is further noted that grounded TSVs within RFIC chips 35 and interposer 45 as exemplified above may enable better impedance matching between connected transmission lines (e.g., a first transmission line formed with a “signal through via” as the inner conductor, connected to a second transmission line within or external to the RFIC chip 35 or interposer 45). This may be accomplished by appropriately selecting the TSV diameter(s) and distance of any grounded TSV fence to the signal through via to produce the desired impedance. Appropriate design thereof may result in a low loss transition.

It is noted here that the implementation of grounded TSVs in RFICs as described above may also be applied to second component layers of phased array antennas in which the third component layer described herein is omitted (e.g., the second component layer is attached directly to a PWB board such as 55). In such embodiments, the RFICs may each include both amplifiers and phase shifters, or separate RFICs may be provided in the second component layer for (primarily) amplifier chips and (primarily) phase shifter chips.

Meanwhile, the upper ends of grounded TSVs 32b1 and 32b2 may be connected to an antenna ground plane 21 within RDL 26 (or alternatively within an internal layer of antenna substrate 22_i above RDL 26) through respective conductive wells 27 or the like. An opening 25 in the ground plane allows a via 29 for a probe feed or side feed, or an EM feed mechanism to RF couple signal energy between antenna element 24_i and amplifier 36. If the connection point at the upper surface of RFIC chip 35_i to amplifier 36 is not aligned with opening 25, a signal trace (not shown) of an RDL 26 may connect the connection point to via 29 or other feed. It is further noted that one or more metal layers within RDL 26 may be utilized to route control or bias voltages from TSVs within RFIC chip 35_i to respective beamforming elements therein.

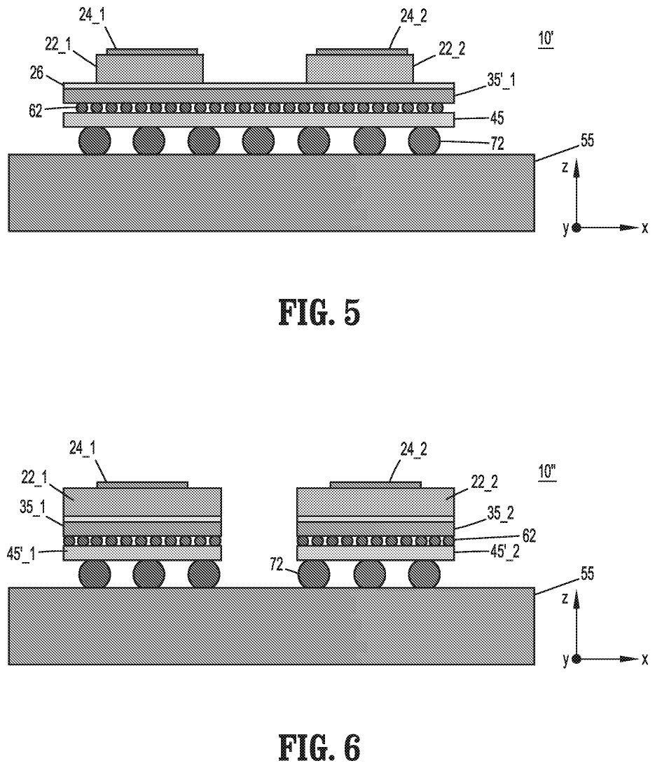

FIG. 5 is an end view of an example phased array antenna, 10′, which may be a modified version of antenna 10 formed as an AESIP. Antenna 10′ differs from antenna 10 illustrated in FIG. 1 by configuring an RFIC chip 35′_1 to be RF coupled to multiple antenna elements 24. Other aspects of antenna 10′ may be the same as discussed above for antenna 10. In one embodiment, RFIC chip 35′_1 is RF coupled to just two antenna elements 24_1 and 24_2, and antenna 10′ is a 1×2 element array or AESIP. In other embodiments, RFIC chip 35′_1 is RF coupled and underlies additional antenna elements 24_3 and 24_4 (as depicted in the plan view of FIG. 2) and antenna 10′ is a 2×2 element array or AESiP. In general, RFIC chip 35′_1 is RF coupled to any suitable number of antenna elements 24.

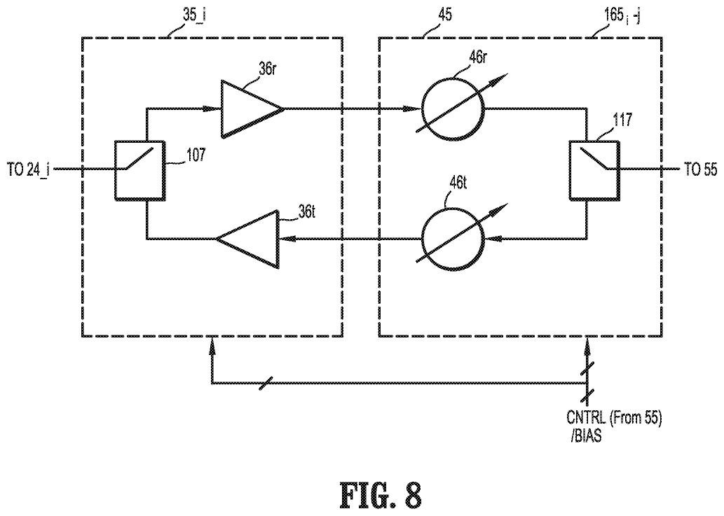

For instance, RFIC chip 35′_1 includes two transmit amplifiers 36 or two receive amplifiers (each not shown), each RF coupled to a respective one of antenna elements 24_1 and 24_2. In other examples, RFIC chip 35′_1 includes three or more amplifiers 36 each RF coupled to at least one antenna element 24. Antenna element sharing between transmit and receive operations can also be implemented in some embodiments by employing at least one transmit/receive (T/R) switch within RFIC chip 35′_1 (discussed below in connection with FIG. 8). Note that in any example of antenna 10′, interposer 45 may have approximately the same footprint as RFIC chip 35′_1 in the xy plane.

A combiner/divider within RFIC chip 35′_1 may: (i) divide an RF transmit signal output from interposer 45 into two divided transmit signals which are amplified by respective amplifiers 36 and then output to antenna elements 21_1 and 21_2, and/or (ii) combine antenna element signals received from antenna elements 21_1 and 21_2 into a combined receive signal that is output to a phase shifter 46 within interposer 45.

FIG. 6 is an end view of a phased array antenna, 10″, according to an embodiment. Antenna 10″ differs from antenna 10 by configuring the third component layer 40 with individual interposer chips 45′_1 and 45′_2 instead of a single structure. Interposer chips 45′_1 and 45′_2 may each include one or more phase shifters 46 and/or other beamforming elements to perform the same or similar functionality as antenna 10 in conjunction with RFIC chips 35 and the other components of antenna 10 discussed above. Other aspects of antenna 10″ may be the same as for antenna 10 already discussed.

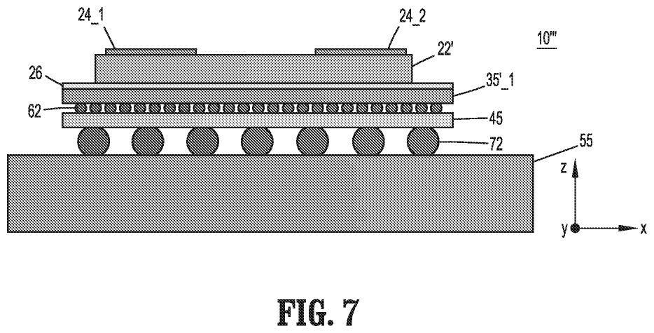

FIG. 7 is an end view of a phased array antenna, 10″, according to an embodiment. Antenna 10″ differs from antenna 10 by substituting a single antenna substrate 22′ for the segregated antenna substrate sections 22_1 to 22_4. Thus, antenna substrate 22′ supports all the antenna elements 24 of antenna 10″. Other aspects of antenna 10″ may be the same as for antenna 10 already discussed above.

FIG. 8 schematically illustrate an example arrangement of beamforming components within any RFIC chip 35_i and interposer 45 in the antennas 10, 10′ or 10″ discussed above, when antenna element sharing between transmit and receive operations is implemented. RFIC chip 35_i may include a first T/R switch 107 (a single pole double throw (SPDT) switch), a transmit amplifier 36t and a receive amplifier 36r. Interposer 45 may include a second T/R switch 117 (also a SPDT switch), a transmit path phase shifter 46t and a receive path phase shifter 46r. All the elements of FIG. 8 may be controlled by control signals or bias signals provided from PWB 55. During transmit operations, T/R switches 117 and 107 are controlled to connect a transmit signal path from PWB 55 to antenna element 24_i through phase shifter 46t and transmit amplifier 36t. During receive operations, T/R switches 117 and 107 are controlled to connect a receive path from antenna element 24 i to PWB 55 through receive amplifier 36r and phase shifter 46r.

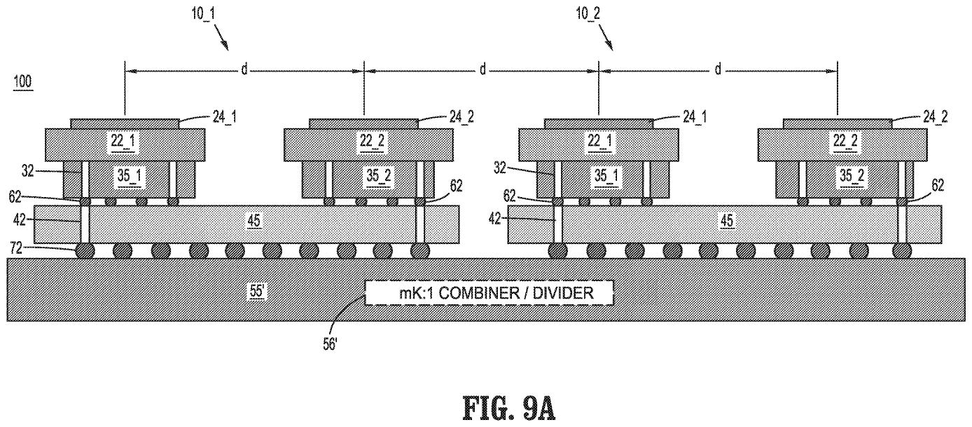

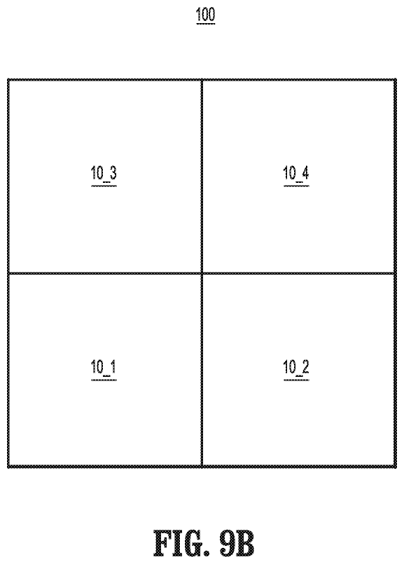

FIG. 9A is an end view of an example phased array antenna, 100, which may be configured with a plurality of subarray antennas as described above. FIG. 9B is an example plan view of antenna 100. Although antenna 100 may generally include any suitable number of subarrays 10, FIGS. 9A and 9B illustrate and example of antenna 100 including four subarrays 10_1, 10_2, 10_3 and 10_4, each of which may be configured as antenna 10 described above (or alternatively as antenna 10′, 10″ or 10′″). In this example, a single PWB 55′ is coupled to and underlies each of the interposers 45 of the subarrays 10_1 to 10_4. PWB 55′ may include an mK:1 combiner/divider 56′, where K is the number of receive path phase shifters 46 in each subarray 10 (or transmit path phase shifters 46) and m is the number of subarrays 10. As described above, each of subarrays 10_1 to 10_4 may be formed as an AESIP and assembled together to form antenna array 100.

Alternatively, antenna array 100 is formed with stacked sets of components, e.g., 80 or 90, formed as AESiPs and adhered to PWB 55′ to form antenna array 100.

Alternatively, PWB 55′ is substituted with four individual PWBs 55 as described above. In this case, for receive operations, the composite receive signal of the four PWBs may be suitably combined by an additional combiner/divider (e.g., in another component layer below component layer 50) to provide a single composite receive signal for the array 100. (If multiple simultaneous beams are formed, there will be a corresponding multiple number of composite receive signals.) Likewise, on transmit, the additional combiner/divider may divide a single input transmit signal into four divided transmit signals which are provided as inputs to the four PWBs 55, respectively. To form antenna 100 in this embodiment, the four individual subarrays 10_1 to 10_4 (each formed as AESiPs with a PWB 55) may be adhered to the additional combiner/divider component by adhering the individual PWBs 55 thereto, to form an overall integrated antenna array structure.

Embodiments of antennas as described above may be particularly advantageous at mm wave frequencies where the inter-element spacings between radiating elements is very small. The stacked construction may allow for performance and manufacturing advantages as described above, as well as cost advantages.

While the technology described herein has been particularly shown and described with reference to example embodiments thereof, it will be understood by those of ordinary skill in the art that various changes in form and details may be made therein without departing from the spirit and scope of the claimed subject matter as defined by the following claims and their equivalents.

1. A phased array antenna comprising:
a first component layer comprising a plurality of antenna elements supported by at least one antenna substrate;
a second component layer, underlying the first component layer, comprising a plurality of radio frequency (RF) integrated circuit (RFIC) chips each comprising at least one amplifier, and each being RF coupled to at least one of the plurality of antenna elements through the at least one antenna substrate; and
a third component layer, underlying the second component layer, comprising a plurality of phase shifters electrically coupled to the plurality of amplifiers, for steering a beam formed by the plurality of antenna elements.

2. The phased array antenna of claim 1, further comprising a fourth component layer underlying the third component layer and comprising a combiner/divider configured to combine a plurality of receive path signals derived from signals received and phase shifted by the plurality of phase shifters to provide a composite receive path signal, and/or to divide an input transmit path signal into a plurality of divided transmit path signals which are output to the plurality of phase shifters.

3. The phased array antenna of claim 2, wherein the fourth component layer comprises control circuitry that outputs control signals to the plurality of phase shifters for controlling respective phase shifts thereof to steer the beam.

4. The phased array antenna of claim 2, wherein:
the fourth component layer comprises biasing circuitry that provides bias voltages to the plurality of amplifiers; and
the third component layer comprises a substrate supporting the plurality of phase shifters, and a plurality of through substrate vias, TSVs, each extending through the substrate and electrically connected on a lower end thereof to the biasing circuitry and on an upper end thereof to an electrical contact of the second component layer connected to one of the amplifiers.

5. The phased array antenna of claim 2, wherein the combining/dividing is performed in the analog domain.

6. The phased array antenna of claim 2, wherein the combining/dividing is performed in the digital domain.

7. The phased array antenna of claim 1, wherein the third component layer is composed primarily of a first substrate material and the RFIC chips are composed primarily of a second, different substrate material.

8. The phased array antenna of claim 7, wherein the first substrate material has a higher thermal conductivity than the second substrate material.

9. The phased array antenna of claim 1, wherein:
the at least one antenna substrate comprises a plurality of segregated antenna substrate sections; and
the first and second component layers together comprise a plurality of active antenna modules, each including: (i) at least one of the antenna elements supported by one of the antenna substrate sections; and (ii) at least one of the RFIC chips adhered to the one of the antenna substrate sections.

10. The phased array antenna of claim 1, wherein each of the RFIC chips is devoid of any phase shifter.

11. The phased array antenna of claim 1, wherein the third component layer comprises a substrate supporting at least two of the phase shifters, the substrate underlying at least two of the RFIC chips and having circuitry formed therein connected to the at least two of the RFIC chips through conductive joints.

12. The phased array antenna of claim 1, wherein the plurality of phase shifters of the third component layer are embedded within a plurality of phase shifter chips, each underlying a respective one of the RFIC chips and adhering to the respective one of the RFIC chips through conductive joints.

13. The phased array antenna of claim 12, wherein:
the at least one antenna substrate comprises a plurality of segregated antenna substrate sections; and
the first, second and third component layers together comprise a plurality of active antenna modules, each including: (i) at least one of the antenna elements supported by a said antenna substrate section; (ii) at least one of the RFIC chips adhered to the antenna substrate section; and (iii) at least one of the phase shifter chips adhered to the at least one of the RFIC chips.

14. The phased array antenna of claim 1, further comprising a redistribution layer, RDL between the antenna elements and the second component layer, the RDL routing RF signals between the amplifiers and corresponding ones of the antenna elements.

15. The phased array antenna of claim 1, wherein the second component layer is electrically connected and adhered to the third component layer with shielded RF interconnects.

16. The phased array antenna of claim 1, wherein the second component layer further includes a plurality of amplitude adjusters for adjusting the beam.

17. The phased array antenna of claim 1, wherein the at least one antenna substrate further includes at least one antenna ground plane(29) electrically connected to ground contacts of the plurality of RFIC chips.

18. The phased array antenna of claim 1, wherein a given RFIC chip of the plurality of RFIC chips includes a via having a lower end connected to an electrical contact at an upper surface of the second component layer and an upper end connected to: (i) the at least one amplifier of the given RFIC chip; (ii) a redistribution layer, RDL between the first and second component layers; or (iii) a ground plane proximate to or forming a lower surface of the at least one antenna substrate.

19. The phased array antenna of claim 1, wherein the at least one amplifier of each of the RFIC chips comprises a transmit path amplifier and/or a receive path amplifier.

20. The phased array antenna of claim 1, wherein a given RFIC chip of the plurality of RFIC chips comprises at least one through substrate via, TSV, connected to a ground conductor of the phased array antenna.

21. The phased array antenna of claim 20, wherein the at least one TSV connected to a ground conductor comprises a plurality of TSVs including TSVs distributed throughout surrounding a circuit element of, and arranged along a periphery of, the given RFIC chip.

22. The phased array antenna of claim 20, wherein the at least one TSV connected to a ground conductor comprises at least ten TSVs distributed throughout the given RFIC chip.

23. The phased array antenna of claim 1, wherein the third component layer comprises:
a substrate supporting at least one of the plurality of phase shifters; and
at least one through substrate via, TSV, extending at least partially through the substrate and connected to a ground conductor of the phased array antenna.

24. A phased array antenna comprising:
a plurality of antenna element systems in a package, AESiPs, each forming a subarray of the phased array antenna and each comprising:
a first component layer comprising a plurality of antenna elements supported by at least one antenna substrate;
a second component layer, underlying the first component layer, comprising a plurality of radio frequency (RF) integrated circuit (RFIC) chips each comprising at least one amplifier, and each being RF coupled to at least one of the plurality of antenna elements through the at least one antenna substrate; and
a third component layer, underlying the second component layer, comprising a plurality of phase shifters electrically coupled to the plurality of amplifiers, for steering a beam formed by the plurality of antenna elements; and
a combiner/divider configured to combine a plurality of receive path signals derived from signals received and phase shifted by the plurality of phase shifters of the plurality of AESiPs to provide a composite receive path signal, and/or to divide an input transmit path signal into a plurality of divided transmit path signals which are output to the plurality of phase shifters.
